(19) United States
(12) Patent Application Publication
(10) Pub. No.: US 2024/0305119 A1
(43) Pub. Date: Sep. 12, 2024

(54) Circuitry for Measurement of Electrochemical Cells

(71) Applicant: Cirrus Logic International Semiconductor Ltd., Edinburgh (GB)

(72) Inventors: John P. LESSO, Edinburgh (GB); Yanto SURYONO, Tokyo (JP); Toru IDO, Kanagawa (JP); Claire MOTION, Edinburgh (GB)

(73) Assignee: Cirrus Logic International Semiconductor Ltd., Edinburgh (GB)

(21) Appl. No.: 18/584,608

(22) Filed: Feb. 22, 2024

Related U.S. Application Data
(60) Provisional application No. 63/450,196, filed on Mar. 6, 2023.

(51) Int. Cl. H02J 7/00; H03H 17/00; H03H 17/02

(52) U.S. Cl. CPC H02J 7/0048; H02J 7/005; H03H 17/0289; H03H 2017/009

(57) ABSTRACT

Circuitry for processing an output of an electrochemical cell comprising a first electrode and a second electrode, the circuitry comprising: drive circuitry configured to apply a stimulus to the first electrode; measurement circuitry configured to obtain an output signal from the output of the electrochemical cell in response to the stimulus; processing circuitry configured to: apply the stimulus to a model of the electrochemical cell; obtain a modelled output signal from the model in response to the stimulus; determine an error in the output signal based on the output signal and the modelled output signal.

### TECHNICAL FIELD

The present disclosure relates to circuitry for processing signals output from electrochemical cells.

### BACKGROUND

Electrochemical cells are widely used in portable devices, in the form of a battery for providing power to a device, or in the form of a sensor for detecting one or more chemical species, analytes. The health of such electrochemical sensors is key to the operation of many devices into which they are integrated. As such, it may be advantageous to determine a state of such sensors during manufacture. In addition, electrical sensors are susceptible to transient effects, such as noise, which can affect measurements made with such devices.

### SUMMARY

According to a first aspect of the disclosure, there is provided Circuitry for processing an output of an electrochemical cell comprising a first electrode and a second electrode, the circuitry comprising: drive circuitry configured to apply a stimulus to the first electrode; measurement circuitry configured to obtain an output signal from the output of the electrochemical cell in response to the stimulus; processing circuitry configured to: apply the stimulus to a model of the electrochemical cell; obtain a modelled output signal from the model in response to the stimulus; determine an error in the modelled output signal based on the output signal and the modelled output signal.

The error may be determined based on a comparison between the output signal and the modelled output signal.

The processing circuitry may be configured to adapt the model in dependence on the stimulus and a comparison of the output signal and the modelled output signal.

The model may comprise a finite impulse response, FIR, filter.

Filter taps of the FIR filter may be adapted in dependence on the comparison of the output signal and the modelled output signal.

The model may comprise one or more IIR filters. The one or more IIR filter may comprise: a first infinite impulse response, IIR, filter configured to filter the stimulus and output a first filtered signal; and a second IIR filter configured to filter the output signal and output a second filtered signal. Filter taps of the first and second IIR filters may be adapted in dependence on the difference between the first and second filters signals.

The processing circuitry may be configured to apply a correction factor to the output signal in dependence on the modelled output signal to obtain a corrected output signal.

The circuitry may be configured detect a transient signal in the output signal based on the modelled output signal. The correction factor may be determined based on the transient signal.

The transient signal may be a Cottrell current in the output signal.

Detecting the transient signal may be performed in response to a change in the stimulus applied to the first electrode, such as a change in a bias voltage.

The processing circuitry may be configured to determine a characteristic of the cell based on the error.

The characteristic may comprise one of the following: a) a fault; b) a state of health; b) a state of charge; c) a power fade; d) a capacity fade; e) ageing.

The processing circuitry may be configured to output an interrupt in response to the error exceeding a predetermined error threshold.

The processing circuitry may be configured to output an enable signal in response to the error falling below a predetermined error threshold.

According to another aspect of the disclosure, there is provided an integrated circuit (IC), comprising circuitry as described above.

According to another aspect of the disclosure, there is provided a wearable device, comprising circuitry as described above. The wearable device may comprise one of an analyte monitor, a glucose monitor, a battery monitor, a mobile computing device, a smart watch, a remote control device, a home automation controller, an audio player, a video player, a mobile telephone, and a smartphone.

According to another aspect of the disclosure, there is provided a method of processing an output of an electrochemical cell comprising a first electrode and a second electrode, the method comprising: apply a stimulus to the first electrode; obtain an output signal from the output of the electrochemical cell in response to the stimulus; apply the stimulus to a model of the electrochemical cell; obtain a modelled output signal from the model in response to the stimulus; determine an error in the output signal based on the output signal and the modelled output signal.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 illustrates a schematic diagram and electrical equivalent circuit for a three-electrode electrochemical cell;

FIG. 2 illustrates a schematic diagram and electrical equivalent circuit for a two-electrode electrochemical cell;

FIG. 3A is a schematic diagram of an example prior art measurement circuit;

FIG. 3B is a schematic diagram of the circuit of FIG. 3A, showing the measurement circuitry in more detail;

FIG. 4 is a graphical illustration of a concentration gradient of a pair of compounds A, B which may be present at the surface of an electrode of an electrochemical cell;

FIG. 5 is a graphical illustration of an example transient Cottrell current which may flow at the working electrode of an electrochemical cell in response to a change in voltage at another electrode of the cell;

FIG. 6 is a schematic diagram of circuitry for processing a measured signal from an electrochemical cell;

FIG. 7 is a circuit diagram of a Randles equivalent circuit;

FIG. 8 is an example of an equivalent circuit for a Warburg impedance;

FIGS. 9 to 11 are schematic diagrams of example drive and measurement circuits; and

FIG. 12 is a block diagram of a device comprising an electrochemical cell.

### DESCRIPTION OF EMBODIMENTS

Electrochemical sensors are widely used for the detection of one or more particular chemical species, analytes, as an oxidation or reduction current. Such sensors comprise an electrochemical cell, consisting of two or more electrodes configured for contact with an analyte whose concentration is to be ascertained. Such sensors also comprise circuitry for driving one or more of the electrodes and for measuring a response at one or more of the electrodes. Batteries also comprise one or more electrochemical cells which typically consist of two or more electrodes (e.g., an anode and a cathode) configured for contact with a conductive electrolyte.

Characteristics of batteries may be ascertained using drive and measurement circuitry similar to that used for characterising electrochemical cells in electrochemical sensors.

Embodiments of the present disclosure provide various novel signal processing techniques for improving the determination of characteristics associated with electrochemical cells and systems (such as sensors, batteries and the like) into which electrochemical cells are incorporated. Embodiments also provide techniques for improving the detection of faults or potential issues with operation of the electrochemical cells and/or devices.

Various implementation details pertaining to drive and measurement circuitry for obtaining characterising impedance measurements of an electrochemical cell are described below. Such embodiments focus primarily on electrochemical cells comprised in sensors (e.g. potentiostats). For example, the embodiments described herein may be implemented as part of an analyte monitoring system, such as a continuous glucose monitor (CGM). It will be appreciated, however, that embodiments are not limited to use with electrochemical sensors. For example, batteries also comprise one or more electrochemical cells which typically consist of two or more electrodes (e.g., an anode and a cathode) configured for contact with a conductive electrolyte. Characteristics of batteries (e.g. comprising lithium ion or silver oxide cell(s)) may be ascertained using drive and measurement circuitry described herein. For example, embodiments of the present disclose may be implemented as part of battery monitoring device (e.g. to monitor the status and/or health of a battery).

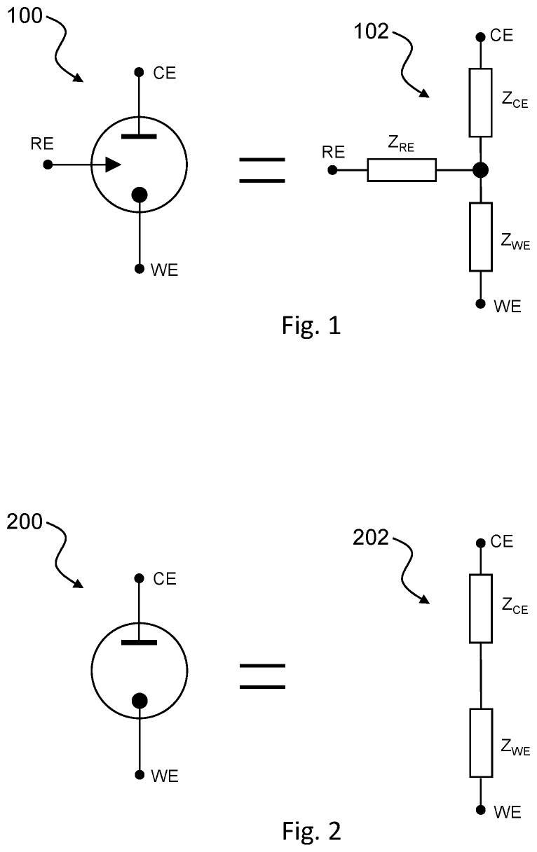

FIG. 1 is a schematic diagram of an example electrochemical cell 100 comprising three electrodes, namely a counter electrode CE, a working electrode WE and a reference electrode RE. FIG. 1 also shows an equivalent circuit 102 for the electrochemical cell 100 comprising a counter electrode impedance ZCE, a working electrode impedance ZWE and a reference electrode impedance ZRE.

FIG. 2 is a schematic diagram of another example electrochemical cell 200 comprising two electrodes, namely a counter electrode CE and a working electrode WE. The electrochemical cell 200 varies for the cell 100 with the omission of the reference electrode RE. FIG. 2 also shows an equivalent circuit 102 for the electrochemical cell 200 comprising a counter electrode impedance ZCE and a working electrode impedance ZWE.

In some embodiments, the working electrode WE comprises an assay or chemical of interest. For example for the analysis of glucose as an analyte, the working electrode may comprise a layer of glucose oxidase. The counter electrode CE is provided to form an electrical or ohmic connection with the working electrode WE. Optionally, the reference electrode is provided, which is typically a sensing point between the working electrode WE and the counter electrode CE, allowing independent measurement of the potential associated with each of the working and counter electrodes WE. CE, rather than just measuring a potential difference between the counter and working electrodes CE, WE.

Embodiments of the disclosure will be described with reference to these example electrochemical cells 100, 200. It will be appreciated, however, that the techniques and apparatus described herein may be used in conjunction with any conceivable electrochemical system, including but not limited to electrochemical cells comprising at least two electrodes (e.g. a counter electrode CE, a working electrode WE and optionally a reference electrode RE), or electrochemical cells with more than three electrodes (e.g. two or more counter electrodes and/or two or more working electrodes). Electrodes of the electrochemical cells described herein may also be referred to as anodes and/or cathodes as is conventional in the field of electrical batteries.

To determine a characteristic of either of the electrochemical cells 100, 200, and therefore an analyte concentration, it is conventional to apply a bias voltage at the counter electrode CE and measure a current at the working electrode WE. When provided, the reference electrode RE may be used to measure a voltage drop between the working electrode WE and the reference electrode RE. The bias voltage is then adjusted to maintain the voltage drop between the reference and working electrodes RE, WE constant. As the resistance in the cell 100 increases, the current measured at the working electrode WE decreases. Likewise, as the resistance in the cell 100 decreases, the current measured at the working electrode WE increases. Thus the electrochemical cell 100 reaches a state of equilibrium where the voltage drop between the reference electrode RE and the working electrode WE is maintained constant. Since the bias voltage at the counter electrode CE and the measured current at WE are known, the resistance of the cell 100 can be ascertained.

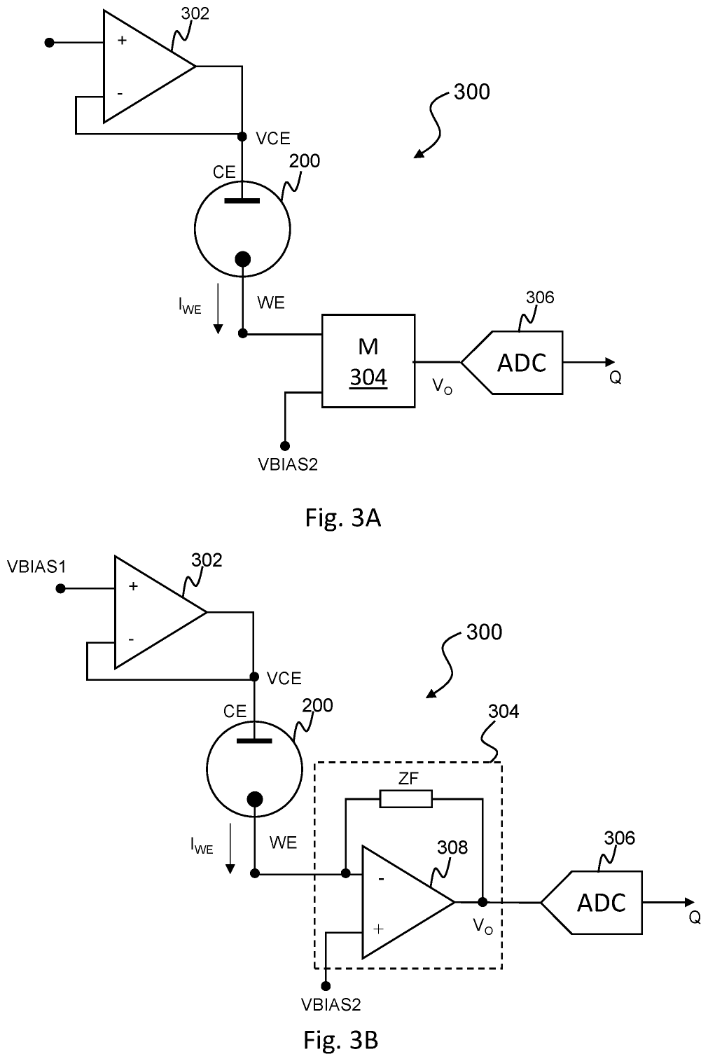

FIG. 3A illustrates an example known drive and measurement circuit 300 which is configured to implement the above explained cell characterisation, specifically for measuring an analyte concentration in the electrochemical cell 200 shown in FIG. 2. The circuit 300 comprises a first amplifier 302 and a measurement circuit 304. Each of the first amplifier 302 and the measurement circuit 304 may comprise one or more op-amps. A non-inverting input of the first amplifier 302 is coupled to a bias voltage VBIAS1 which may be generated by a digital-to-analog converter DAC (not shown). An inverting input of the first amplifier 302 is coupled to the counter electrode CE. An output of the first amplifier 302 is coupled to the counter electrode CE and configured to drive the counter electrode CE with a counter electrode bias voltage VCE. The counter electrode bias voltage VCE applied at the counter electrode CE by the first amplifier 202 is proportional to the difference between the bias voltage VBIAS1 and the voltage at the counter electrode CE.

The measurement circuit 304 is coupled between the working electrode WE and an analog-to-digital converter (ADC) 306. The measurement circuit 304 is operable to output to the ADC 306 a signal proportional to the current flowing from the working electrode WE. The ADC 306 then converts the signal output from the measurement circuit 304 to a digital output signal Q which represents the current flowing from the working electrode WE.

The measurement circuit 304 typically implemented as a transimpedance amplifier or a current conveyor.

FIG. 3B illustrates an example implementation of the drive and measurement circuit 300, the measurement circuit 304 implemented as a transimpedance amplifier comprising a second amplifier 308. An inverting input of the second amplifier 308 is coupled to the working electrode WE and a non-inverting input of the second amplifier 308 is coupled to a fixed vias voltage VBIAS2, for example ground GND. A feedback impedance ZF is coupled between the non-inverting input and an output of the second amplifier 308. As such, the second amplifier 308 operates as a transimpedance amplifier. The second amplifier 308 is thus operable to output a voltage VO which is proportional to the current IWE at the working electrode WE. The output voltage VO is then provided to the analog-to-digital converter (ADC) 306 which outputs a digital output Q which represents the current IWE at the working electrode WE.

To bias the counter electrode CE, and therefore the electrochemical cell 200, at different voltages, the bias voltage VBIAS1 provided to the first amplifier 302 may be adjusted. The bias voltage VBIAS1 may be adjusted between a reference voltage (e.g. ground or zero volts) and the supply voltage VDD. With the non-inverting input of the second amplifier 204 is set at VDD/2, a positive bias may be applied to the cell 200 by maintaining the bias voltage VBIAS above VDD/2. Likewise, a negative bias may be applied to the cell 100 by maintaining the bias voltage VBIAS below VDD/2.

The drive and measurement circuitry 200 described above may be used to implement electro-impedance spectroscopy (EIS) on the cell 100.

To implement EIS, it is conventional to modulate the bias voltage VBIAS1, for example by applying a sine wave having a modulated frequency and/or amplitude. The measurement circuit 304 and ADC 306 may then be used to measure a response of the cell 200 to that sine wave, in the form of the output voltage VO. The frequency of the sine wave may be adjusted over a range of frequencies in order to obtain a series of frequency dependent impedance measurements of the cell 200. Alternatively, one or more frequencies of interest may be known (identified, estimated, modelled or otherwise predetermined) such that the sine wave which is applied is at that frequency of interest. Each frequency of interest may be chosen to minimize variation in measurements or maximise a response of the cell for determining a particular characteristic.

An alternative known approach to the above EIS technique is chronoamperometry (CA) in which a step or impulse function stimulus is applied to the cell 200. The resultant signal occurring at the working electrode caused by the change in stimulus amplitude is then monitored as a function of time. A transfer function between the stimulus and a response of the cell 200 to that stimulus can then be estimated or inferred.

Electrochemical cells such as the cells 100, 200 described above suffer from various non-ideal effects which lead to both steady state and transient errors in signals obtained from them.

For example, ageing of electrochemical cells occurs from the time of their initial manufacture. Many different ageing mechanisms may affect a cell, such as loss of active material, active material dissolution, surface cracking, pore clogging, solid electrolyte interphase (SEI) kinetics, diffusion into SEI, and electron tunnelling to name a few. In battery cells, these mechanisms can lead to capacity fade, power fade, and reduced charge. In electrochemical sensors, these mechanisms can lead to changes electrode area, impedance characteristics, and ion selective potential difference values. Such ageing can lead to both long term sensor drift and changes in transient behaviour. Eventually deterioration of a cell may lead to a fault or malfunction such that the cell is inoperable or cannot function to the desired degree of accuracy.

In addition to the above ageing effects, conditions at a cell can lead to transient and steady state errors which affect signals obtained therefrom. As noted above, even when operating normally, electrochemical cells exhibit transient characteristics, particularly in response to transitions or changes in signals applied to them. Such transitions may occur on startup or warmup of a device incorporating the cell, for example when a bias signal (e.g. voltage) is first applied to the cell, or when a device is first inserted into a measurement environment (e.g. skin for CGM). Additionally, transitions may occur when a cell is being interrogated with an impulse or step stimulus (as is the case for CA). In each case, the voltage applied to an electrode of the cell changes and this change can lead to a transient artefact in a measured signal output from the cell. Moreover, such transient artefacts are dependent on many factors which cannot practically be controlled.

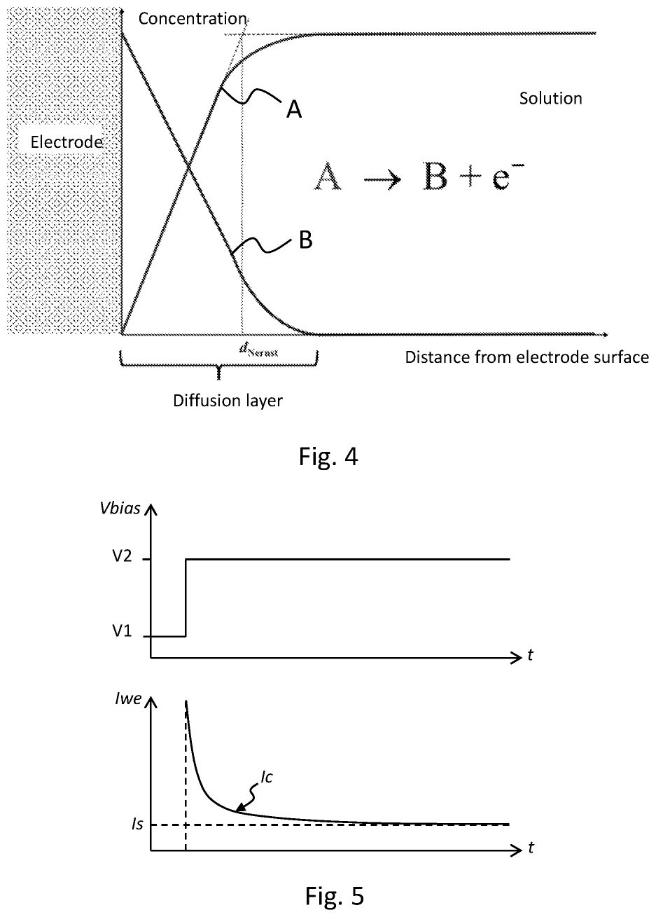

The generation of some such artefacts will now be described with reference to FIGS. 4 and 5 in relation to current. The generation of current in an electrochemical cell, such as the cells 100, 200 shown in FIGS. 1 and 2 is accomplished by one of three mechanisms: diffusion in a concentration gradient, migration in a potential gradient, and convection. In cells such as those used in analyte measurement, the overarching mechanism is diffusion due to concentration gradient.

FIG. 4 illustrates this by plotting diffusion profiles of two compounds A, B as a function of distance from an electrode surface. A concentration gradient will build up at the interface the electrode causing a diffusion layer to form when a compound A is oxidised to form a compound B on the electrode surface. The distance from the interface to the intercept of the two linear parts of the concentration profile of each of the two compounds A, B is known as the Nernst diffusion layer thickness dNernst. The diffusion profile depends on the diffusion coefficients of the diffusion ions (or molecules) and is a function of time. This means that the diffusion layer thickness dNernst grows with time whilst the concentration gradients of each of the compounds A, B decrease with time. It follows that since the concentration gradients decrease in time, current in the cell also decreases over time. If diffusion is the only process limiting current flow, for a planar electrode, the current decay is described by the Cottrell equation which defines a Cottrell current Ic as follows:

$$Ic = nF {A}_{electrode} {c}_{A . bulk} \sqrt{\frac{{D}_{A}}{π t}}$$

According to the above equation, the current decreases with \sqrt{t}.

Thus, when a voltage across an electrochemical cell is altered, a decaying noise current, referred to as the Cottrell current (Ic), begins to flow through the cell which can adversely affect signals measured at the cell.

FIG. 5 is a graphical illustration of a step in the bias voltage VBIAS1 applied to the counter electrode CE of the cell 200 shown in FIG. 2, together with the working electrode current IWE observable at the working electrode WE of the cell 200. It can be seen that shortly after the step is applied, the Cottrell current Ic is massive when compared to the signal current Is of interest.

It can be seen from the Cottrell equation referred to above that the Cottrell current Ic is dependent on electrode area A. It will be appreciated therefore that when an electrode is first introduced into a measurement environment, effective electrode area may change over time, leading to changes in the Cottrell current Ic profile for that electrode. In the case of analyte sensors used to measure analytes in a human or animal subject, a sensor may be implanted under the skin of the subject, after which the sensor electrodes experience wetting or hydration over time. During this period of wetting, the active area of each electrode of the sensor increases. This change in effective electrode area leads to a change in the Cottrell current Ic which can affect measurements obtained from the sensor during the time following insertion until a wetting equilibrium is reached.

Embodiments of the present disclosure aim to address or at least ameliorate one or more of the above issues by providing circuitry and methods which are able to monitor one or more characteristics of an electrochemical cell (and the sensor into which it may be incorporated) over time. This is achieved by introduction of an electrochemical cell model of the electrochemical cell which can be stimulated with the same or similar stimulus to that applied to the electrochemical cell. A response to each of the cell and the cell model can be measured based on these measurements, certain inferences can be made as to the condition of the cell. Such inferences may include but are not limited to an error in a signal obtained from the electrochemical cell, a fault in the cell, a condition at the cell. The error may be due to any number of factors (a fault or degradation of the cell, a transient noise signal corrupting a signal of interest, or the like). The determined error may be used to correct one or more signals obtained from the cell. Additionally or alternatively, the determined error may be used to control or adjust future stimuli applied to the cell for measurement. Additionally, or alternatively, an interrupt or warning may be generated in response to the error, or the error falling outside of some predetermined thresholds or threshold ranges.

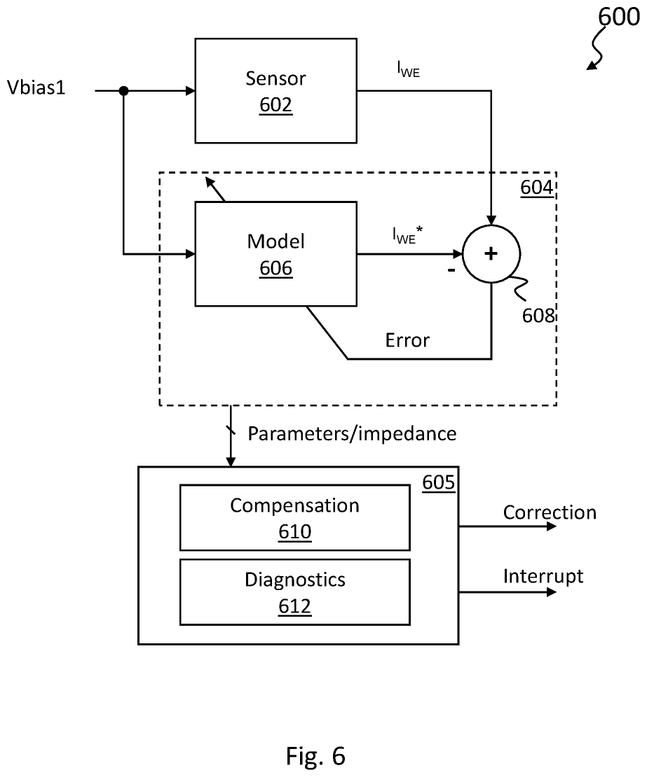

FIG. 6 is a block diagram of a system 600 according to embodiments of the present disclosure. The system 600 comprises a sensor 602, system identification (ID) circuitry 604 for characterising the sensor 602, and processing circuitry 605 for processing one or more signals output from the system ID circuitry.

The sensor 602 comprises an electrochemical cell, such as the cells 100, 200 above. Optionally, the sensor 602 may also comprise any back end measurement circuitry used to process signals output from the sensor. For example, with reference to FIG. 3A, the sensor 602 may comprise the measurement circuitry 304 and/or the ADC 306. Alternatively, such processing circuitry may be incorporated into the system ID circuitry 604. In the embodiments shown, the sensor 602 outputs a measurement current IWE. In other embodiments, the sensor 602 may output a voltage signal (e.g. for potentiometric sensors).

The system ID circuitry 604 comprises a sensor model 606 which may model the sensor 602 or the cell comprised therein. Additionally, the system ID circuitry 604 comprises a difference module 608.

The processing circuitry 605 may comprise compensation circuitry 608 and/or diagnostic circuitry 612.

The compensation circuitry 608 may be configured to determine compensation or correction factors for correcting signals derived from the sensor 602. Such compensation factors may be derived from signals obtained from the system ID circuitry 604. Compensation or correction factors may be output from the processing circuitry 605 to be used in further processing, for example to correct signals applied to or obtained from the sensor 602. Compensation may comprise adjustment of gain and/or offset which may be fixed or transient.

The diagnostic circuitry 612 may be configured to determine one or more conditions at the sensor 602 or a device into which the sensor 602 may be integrated. Such conditions may indicate a fault associated with the sensor 602 or deterioration of the sensor 602 which may be affecting its performance. In response to detecting a condition, the processing circuitry 605 may output one or more interrupts or warnings, and/or may output signals to adjust downstream processing of signals obtained from the sensor 602.

The sensor 602 and sensor model 606 are configured to receive a common bias voltage Vbias 1 and output a working electrode current IWE and modelled working electrode current IWE* respectively. These currents IWE, IWE* are provided to the difference module 608 which subtracts the modelled working electrode current IWE* from the working electrode current IWE to obtain a difference (or error) between the working electrode current IWE and the modelled working electrode current IWE*.

The derived error signal ERROR may itself be used for fault detection or signal compensation/correction as will be described in more detail below.

Additionally or alternatively, the error signal ERROR may be provided to the sensor model 606 for adaptation in dependence on the error signal ERROR to minimize error between the working electrode current IWE and the modelled working electrode current IWE*.

Adaptation of the sensor model 606 may be performed in a known manner, such as using an infinite impulse response (IIR) filter, a finite impulse response (FIR) filter, or through deconvolution, implementation of which is described below. In some embodiments, the sensor model 606 may be adapted in the digital domain, for example in software. Alternatively, the sensor model 606 may be adapted using analog processing circuitry, such as a series of integrators, gain values and interconnects as is known in the art.

The sensor model 606 is configured to model the sensor 602 in any conceivable manner. For example, the sensor model 606 may implement parametric modelling techniques, non-parametric modelling techniques, or a combination of both.

To parametrically model the sensor 602, the sensor model 606 may be configured to match its response to an equivalent circuit model of the sensor 602. For example the sensor 602 may be modelled using circuit components, and the sensor model 606 may assign values to such components which result in the circuit model 606 having a similar output to that sensor 602 in response to a known stimulus (i.e. Vbias1).

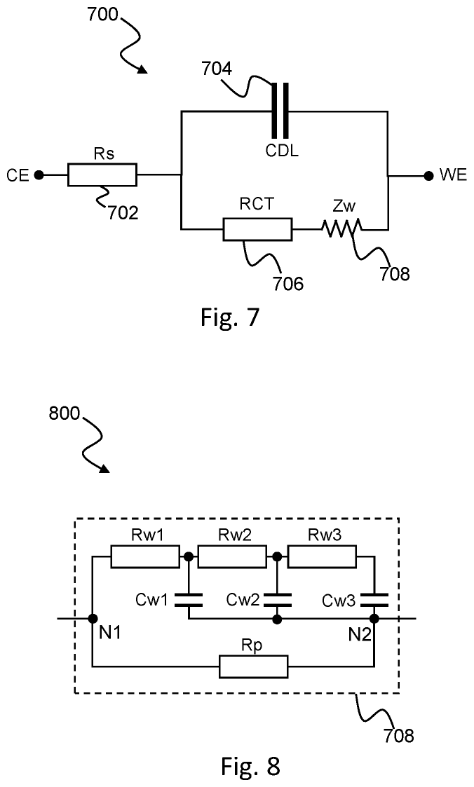

FIG. 7 shows is a schematic diagram of an example circuit model 700 known in the art as a Randles circuit. The circuit model 700 comprises a series resistor 702 having an ionic resistance Rs, a load capacitor 704 having a double layer capacitance CDL coupled in series with the series resistor 702, a charge transfer resistor 706 having charge transfer resistance RCT, and a series Warburg impedance 708 with impedance ZW. The charge transfer resistance RCT represents the resistance associated with the faradaic reaction taking place in the cell. Thus, the charge transfer resistor 706 and the series impedance 708 are coupled in series and provided in parallel with the load capacitor 704. The series impedance 708 represents resistance associated with diffusion of reactants in the cell (as noted above, the rate of the faradaic reaction is controlled by diffusion of reactants in the cell). Thus, the series impedance 708 is provided in series with the parallel combination of the resistor 702 and the load capacitor 704.

FIG. 8 is a circuit diagram of an example model implementation of the series impedance 708 which may be used in conjunction with the circuit model 700 shown in FIG. 7. In this example the series impedance 708 comprises first, second and third Warburg resistances Rw1, Rw2, Rw3 connected in series between first and second terminals N1, N2, the series combination of these Warburg resistances Rw1, Rw2, Rw3 connected in parallel to a parallel resistance Rp. A first Warburg capacitance Cw1 is coupled between the first and second Warburg resistances Rw1, Rw2 and the second terminal N2. A second Warburg capacitance Cw2 is coupled between the second and third Warburg capacitances Cw2, Cw3 and the second terminal N2. A third Warburg capacitance Cw3 is coupled between the third Warburg resistance Rw3 and the second terminal N2.

It will be appreciated that FIGS. 7 and 8 depict one example equivalent circuit model for the sensor 602. However, any conceivable equivalent circuit may be used to in this parametric approach.

In any case, once the circuit parameters of the equivalent circuit model have been obtained, such parameters may be output by the model 606 for further processing, for example to identify the sensor 602 and/or one or more characteristics thereof. Additionally or alternatively, these parameters may be used to detect faults or compensate for sensor error, as has been previously described and will be described in more detail below.

To model the sensor non-parametrically, the sensor model 606 may be configured to estimate an impedance Z(f) of the sensor as a function frequency. This may be achieved using various techniques, examples of which will now be described.

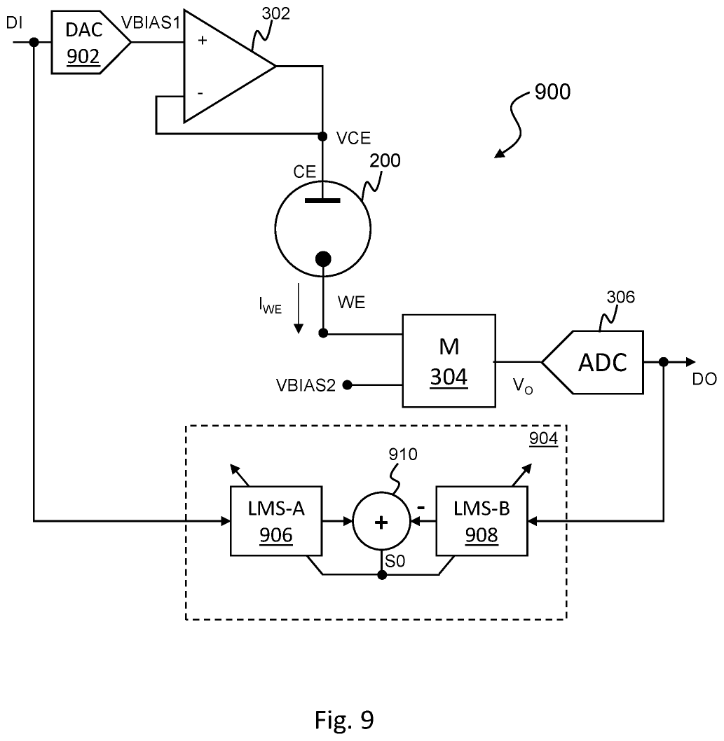

FIG. 9 is a schematic diagram of drive and measurement circuitry 900 for performing non-parametric system identification using infinite impulse response (IIR) filters. The circuitry 900 is a variation of the circuitry 300 shown in FIG. 3A, like parts being given like numberings. In this example, the circuitry 900 comprises a DAC 902 for generating the bias voltage BVIAS1 provided to the non-inverting input of the first amplifier 302. In addition, the circuitry 900 further comprises system ID circuitry 904 comprising a first least mean squared (LMS) filter 906, a second LMS filter 908, and an adder 910.

The system ID circuitry 904 is configured to receive a digital input signal DI provided as an input to the DAC 902 and a digital output signal DO output from the ADC 306 and representing the working electrode voltage IWE at the working electrode WE of the electrochemical cell 200. The digital input signal DI is provided as an input to the first LMS filter 906. The digital output signal DO is provided as an input the second LMS filter 908. Outputs of the first and second LMS filters 906, 908 are provided to the adder 910 which is configured to sum the outputs of the first and second LMS filters 906, 908 to generate a combined filtered signal S0. The combined filtered signal S0 is provided to each of the first and second LMS filter 906, 908 and used to adapt respective LMS filters 906, 908. S0 may be defined as follows:

$$S 0 = \frac{DI ( t ) * A ( t ) - DO ( t ) * B ( t )}{2}$$

Where * denotes convolution, A(t) is the impulse response of the first LMS filter 906, and B(t) is the impulse response of the second LMS filter 908. Where the first and second LMS filters 906, 908 are implemented as FIR filters, A(t) and B(t) represent filter tap values of the first and second LMS filters 906, 908, respectively.

The objective of the system ID circuitry 904 is to minimize SO by using the derivatives

$$\frac{dS 0}{dA}$$

and

$$\frac{dS 0}{dB}$$

together with gradient descent to adjust the first and second coefficients A(t) and B(t) substantially simultaneously.

In the example shown in FIG. 9, LMS filter 906, 908 are used. It will be appreciated that one or both of the LMS filters 906, 908 may be replaced with any other suitable infinite impulse response (IIR) filter known in the art.

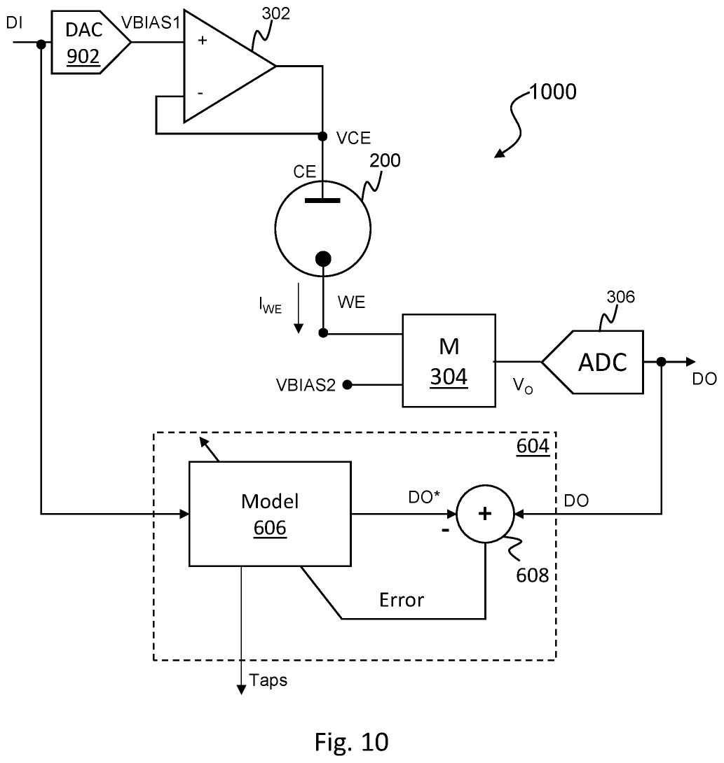

FIG. 10 is a schematic diagram of drive and measurement circuitry 1000 which implements non-parametric system identification using a finite impulse response (FIR) filter. The circuitry 1000 is a variation of the circuitry 900 shown in FIG. 9, like parts being given like numberings. The circuitry 1000 of FIG. 10 differs from that of FIG. 9 in that the system ID circuitry 904 has been replaced with the system ID circuitry 602 shown in FIG. 6 configured to operate in the digital domain. As such, the first amplifier 302, the cell 200, and the measurement circuitry 304 are equivalent to the sensor 602 of FIG. 6.

Thus, a common digital input DO is provided to the DAC 902 and the model 606. The digital output DO representing the working electrode current IWE, is provided to the difference module 608. A modelled digital output DO* is output from the model 606 and provided to the difference module 608. The difference module 608 subtracts the modelled digital output DO* from the digital output DO to obtain a difference (or error) between the actual and modelled digital outputs DO, DO*.

In this example, the model 606 is implemented as a load model adaptive filter. Thus, the model 606 may be implemented as a finite impulse response (FIR) filter which adapts based on an error between its output DO* and the digital output DO from the ADC 306. Filter tap values of the load model adaptive filter may then be used for calibration/correction, fault detection or other diagnostic analysis.

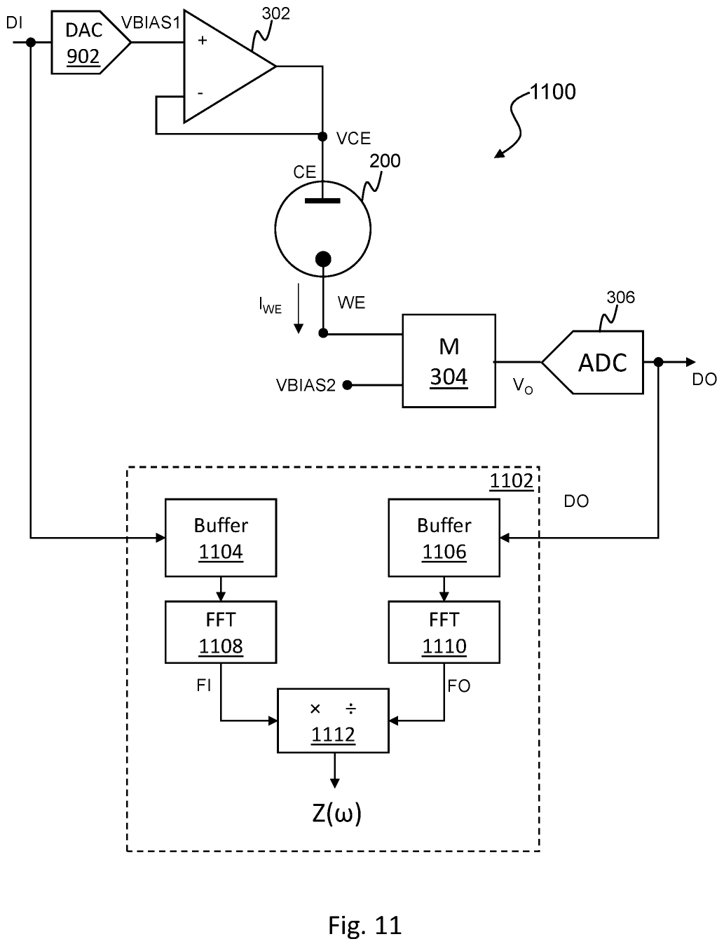

FIG. 11 is a schematic diagram of drive and measurement circuitry 1100 which implements non-parametric system identification using deconvolution. The circuitry 1100 is a variation of the circuitry 900 shown in FIG. 9, like parts being given like numberings. The circuitry 1100 of FIG. 11 differs from that of FIG. 9 in that the system ID circuitry 904 has been replaced with a system ID circuitry 1102.

The system ID circuitry 1102 comprises first and second buffers 1104, 1106, first and second Fourier transform (FT) circuitry 1108, 1110, multiplication circuitry 1112, and impedance circuitry 1114. The digital input signal DI is provided to the first buffer 1104 which buffers the digital input DI before being provided to the first FT module 1108. The first FT module 1108 is thus configured to perform a Fourier transform on the digital input signal DI to obtain a transformed input signal FI. The digital output signal DO is provided to the second buffer 1106 which buffers the digital output signal DO before being provided to the second FT module 1110. The second FT module 1110 is then configured to perform a Fourier transform on digital output signal DO to obtain a transformed output signal FO. The transformed input and output signals FI, FO are then provided to the division circuitry 1112 which is configured to obtain a frequency domain representation of the impedance of the cell 200.

The division circuitry 1112 may be configured to perform an element-wise complex division of the transformed input signal FI by the transformed output signal FO, i.e. FI/FO. In more details, impedance Z(t) in the time domain may be defined as follows, where V(t) is the input voltage, and I(t) is the output current:

$$V ( t ) = I ( t ) * Z ( t )$$

In the frequency domain, the above convolution becomes a multiplication, i.e.:

$$V ( ω ) = I ( ω ) \cdot Z ( ω )$$

As such, the frequency domain impedance Z(ω) is defined as follows:

$$Z ( ω ) = \frac{V ( ω )}{I ( ω )} = FI / FO$$

Thus, the division circuitry 1112 is configured to calculate the frequency domain impedance Z(ω) of the cell 100.

In all of the above examples, system identification is performed to obtain parameters or frequency dependent impedance estimates for the sensor or cell under test. These parameters or impedance estimates may collectively be referred to as characteristics of the sensor or cell under test.

The determined characteristics may be used in a number of ways to determine useful information regarding the cell. For clarity, such use will now be described with reference to FIG. 6 but is equally applicable to all embodiments described herein.

For example, the model 604 or characteristics obtained therefrom may be used to estimate a transient current in the electrochemical cell, such as a Cottrell current or current associated with wetting or hydration of electrodes, which may flow in response to a step or impulse stimulus. Referring to FIG. 6 for example, the transient current estimate may be subtracted from the signal output from the sensor 602 to provide a corrected output. This has the advantage of enabling a valid read of the output signal sooner during decay of the transient (Cottrell) current associated with such stimuli (or warm up of the sensor 602). Additionally or alternatively, the transient current may be monitored to determine a point at which the output signal can be validly relied upon for accurate measurements of characteristics of a cell comprised in the sensor 602.

As explained above, transients may exhibit due to a change in the applied stimulus electrochemical, such as in response to transitions or changes in signals applied to the cell. Such transitions may occur on startup or warmup of a device incorporating the cell, for example when a bias signal (e.g. voltage) is first applied to the cell, or when a device is first inserted into a measurement environment (e.g. skin for CGM). Additionally, transitions may occur when a cell is being interrogated with an impulse or step stimulus (as is the case for CA). In each case, the stimulus applied to the sensor 602 changes and this change can lead to a transient artefact in a measured signal output from the sensor 602. Accordingly, the model 604 may be configured only to monitor for at transient at or shortly after a change in the signal applied to the sensor 604, i.e. at times at which a transient may be expected in the response of the sensor 602 to changes in applied stimuli.

In another example, the model or characteristics obtained therefrom may be used to estimate a one or more conditions at the cell, such as a health metric associated with the cell. Such health metric may be associated with ageing for reasons discussed above. In another related example, the model or characteristic obtained therefrom may be used to detect a fault condition of the cell.

The health metric or fault detection operations may be performed in an online mode in which a stimulus is applied to the sensor 602 and an input of the model 604 and an output of the model 604 is used to determine a health metric of the sensor 602 and/or detect a fault (or a likelihood that the sensor 602 has a fault). Additionally or alternatively, the health metric or fault detection operations may be performed offline (i.e. in an offline or predictive mode). In this mode, a stimulus is applied to an input of the model 604 without being applied to the sensor 602 and the output of the model 604 may be used to determine either the health metric, to detect a fault (or likelihood thereof), and/or determine whether a proposed stimulus will interfere with a measurement of the output of the sensor. Such interference may be related to an impact of a given step or impulse. A prediction may be made as to the impact and the size of the step of impulse adjusted to reduce the impact of the stimulus amplitude on the accuracy of the output signal from the sensor 602.

As noted, above, the cells 100, 200 and circuitry 600, 900, 1000, 1100 may be integrated into electronic devices to be utilised for a particular practical application, such as sensing or providing power.

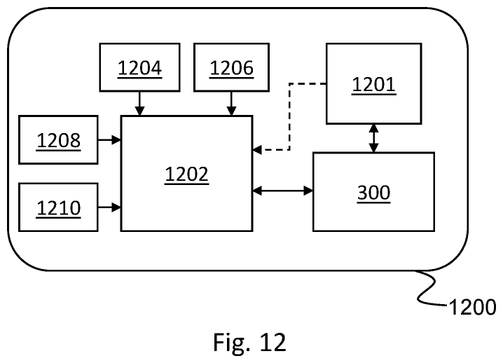

FIG. 12 illustrates an example electronic device 1200 comprising a sensor 1201 according to embodiments of the present disclosure. The example shown in FIG. 12 is provided for explanatory purposes only and may comprise one or more additional components or fewer components depending on the specific application of the electronic device 1200. In the example in FIG. 12, the device 1200 comprises the drive and measurement circuit 300 of FIG. 3A. It will be appreciated that the circuit 300 may be replaced with the measurement circuit 900, 1000, 1100 of any of FIG. 9, 10 or 11 without departing from the scope of the present disclosure.

The electronic device 1200 may comprise a processor 1202 which may be configured to control the drive and measurement circuit 300 and process signals received from the drive and measurement circuit 300. Thus, the processor 1202 may implement the functionality of one or more of the system ID circuitry 604, 904, 1102 described above. The processor 1202 may be an applications processor AP, a digital signal processor (DSP). The processor may be formed of a single processor or multiple processors. For example the electronic device 1200 may comprise an AP and a DSP.

In some embodiments, the processor 1202 or portions thereof may be implemented outside of the device 1200, for example remote from the device 1200 on a host device or server.

The device 1200 may further comprise a memory 1204, which may in practice be provided as a single component or as multiple components. The memory 1204 may be provided for storing data and/or program instructions. The memory 1204 may comprise non-volatile memory. The memory 1204 may additionally or alternatively comprise volatile memory.

The device 1200 may further comprise a transceiver 1206, which may be provided to communicate (wired or wirelessly) with external devices, such as a host device (e.g. mobile device or smartphone) or a remote device (e.g. via the internet). The transceiver may be a Bluetooth transceiver.

The device 1200 may further comprise a temperature sensor 1208 and may comprise other sensors (not shown).

The device 1200 may further comprise a real time clock (RTC) 1210 which may be used to timestamp data obtained from the sensor 1201 or data derived from data obtained from the sensor 1201, which may be stored in the memory 1204.

The device 1200 may further comprise an external or internal power source (such as a battery). It will be appreciated that where the cell 200 is a battery, the sensor 1201 may provide power to the device 1200 as denoted by the dotted line between the cell 200 and the processor 1202.

Non-limited examples of the electronic device 1200 include an analyte monitoring device or an analyte sensing device, a continuous glucose monitor, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

In some embodiments, the electronic device 1200 comprises an analyte (e.g. glucose) monitoring device which may be affixed to the skin of a subject for measuring an analyte in the blood that subject. Such devices have a fixed lifespan. As such, any calibration or correction data which has been obtained during the lifespan of one device may be useful in the calibration of another device. Accordingly, a first device, such as the device 1200, may be configured to transfer data to a second device (similar to the device 1200) to be affixed to the subject. The second device may rely solely on the calibration information from the first device, or some combination of that calibration information and calibration information stored on the second device (which may be a factory default calibration). The transfer of data to the second device may be directly from the first device, or from a host device (such as a smartphone or server) or via an applicator used to affix the second device on the subject.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry for processing an output of an electrochemical cell comprising a first electrode and a second electrode, the circuitry comprising:
drive circuitry configured to apply a stimulus to the first electrode;
measurement circuitry configured to obtain an output signal from the output of the electrochemical cell in response to the stimulus;
processing circuitry configured to:
apply the stimulus to a model of the electrochemical cell;
obtain a modelled output signal from the model in response to the stimulus;
determine an error in the modelled output signal based on the output signal and the modelled output signal.

2. Circuitry of claim 1, wherein the error is determined based on a comparison between the output signal and the modelled output signal.

3. Circuitry of claim 2, wherein the processing circuitry is configured to:
adapt the model in dependence on the stimulus and a comparison of the output signal and the modelled output signal.

4. Circuitry of claim 3, wherein the model comprises a finite impulse response, FIR, filter.

5. Circuitry of claim 4, wherein filter taps of the FIR filter are adapted in dependence on the comparison of the output signal and the modelled output signal.

6. Circuitry of claim 3, wherein the model comprises one or more infinite impulse response, IIR, filters.

7. Circuitry of claim 6, wherein the one or more IIR filters comprise:
a first IIR filter configured to filter the stimulus and output a first filtered signal; and
a second IIR filter configured to filter the output signal and output a second filtered signal,
wherein filter taps of the first and second IIR filters are adapted in dependence on the difference between the first and second filters signals.

8. Circuitry of claim 1, wherein the processing circuitry is configured to:
apply a correction factor to the output signal in dependence on the modelled output signal to obtain a corrected output signal.

9. Circuitry of claim 8, wherein the processing circuitry is configured to:
detect a transient signal in the output signal based on the modelled output signal, wherein the correction factor is determined based on the transient signal.

10. Circuitry of claim 9, wherein the transient signal is a Cottrell current in the output signal.

11. Circuitry of claim 9, wherein detecting the transient signal is performed in response to a change in the stimulus applied to the first electrode.

12. Circuitry of claim 1, wherein the processing circuitry is configured to determine a characteristic of the cell based on the error.

13. Circuitry of claim 12, wherein the characteristic comprises one of the following:
a) a fault;
b) a state of health;
b) a state of charge;
c) a power fade;
d) a capacity fade;
e) ageing.

14. Circuitry of claim 1, wherein the processing circuitry is configured to:
output an interrupt in response to the error exceeding a predetermined error threshold.

15. Circuitry of claim 1, wherein the processing circuitry is configured to:
output an enable signal in response to the error falling below a predetermined error threshold.

16. An integrated circuit (IC), comprising the circuitry of claim 1.

17. A wearable device, comprising:
circuitry of claim 1.

18. The wearable device of claim 17, wherein the wearable device comprises one of an analyte monitor, a glucose monitor, a battery monitor, a mobile computing device, a smart watch, a remote control device, a home automation controller, an audio player, a video player, a mobile telephone, and a smartphone.

19. A method of processing an output of an electrochemical cell comprising a first electrode and a second electrode, the method comprising:
apply a stimulus to the first electrode;
obtain an output signal from the output of the electrochemical cell in response to the stimulus;
apply the stimulus to a model of the electrochemical cell;
obtain a modelled output signal from the model in response to the stimulus;
determine an error in the output signal based on the output signal and the modelled output signal.
